(19) United States
(12) Patent Application Publication
(10) Pub. No.: US 2025/0309813 A1
(43) Pub. Date: Oct. 2, 2025

(54) DRIVE STATE DETECTION DEVICE

(71) Applicant: ALPS ALPINE CO., LTD., Tokyo (JP)

(72) Inventor: Kazuhiro HAMAMATSU, Miyagi (JP)

(21) Appl. No.: 19/084,058

(22) Filed: Mar. 19, 2025

(30) Foreign Application Priority Data
Mar. 29, 2024 (JP) 2024-056697

(51) Int. Cl. H02P 29/50

(52) U.S. Cl. CPC H02P 29/50

(57) ABSTRACT

A drive state detection device includes a current detection unit configured to detect a drive current during driving of an inductive load; a voltage detection unit configured to detect an interterminal voltage during the driving of the inductive load; a variable filter configured to allow passage of a component of a predetermined frequency pass band, the component being of the drive current detected by the current detection unit; a signal generation unit configured to generate a pulse signal from a waveform of the drive current after the passage through the variable filter; and an arithmetic logic unit configured to detect a state of the inductive load in accordance with the drive current detected by the current detection unit, the interterminal voltage detected by the voltage detection unit, and the pulse signal generated by the signal generation unit.

### CROSS-REFERENCE TO RELATED APPLICATIONS

The present application is based on and claims priority to Japanese Patent Application No. 2024-056697 filed on Mar. 29, 2024, the entire contents of which are hereby incorporated by reference.

### BACKGROUND

### 1. Field of the Invention

The present disclosure relates to a drive state detection device.

### 2. Description of the Related Art

PCT Japanese Translation Patent Publication No. 1999-514094 suggests that a motor current with ripple fluctuation has an exponential form, and a blocking current is estimated from the exponential form.

Japanese Laid-Open Patent Application No. 1996-25198 describes performing detection six times as the number of sampling, “n”, thereby detecting an inrush current flowing at the time of start of driving of a direct current motor. Japanese Laid-Open Patent Application No. 1996-25198 also describes that in accordance with the position of a rotor at the time of start of the driving, there are a case in which two peaks form in the waveform of the inrush current and a case in which only one peak forms in the waveform of the inrush current.

### SUMMARY

A drive state detection device according to an embodiment of the present disclosure includes: a current detection unit configured to detect a drive current during driving of an inductive load; a voltage detection unit configured to detect an interterminal voltage during the driving of the inductive load; a variable filter configured to allow passage of a component of a predetermined frequency pass band, the component being of the drive current detected by the current detection unit; a signal generation unit configured to generate a pulse signal from a waveform of the drive current after the passage through the variable filter; and an arithmetic logic unit configured to detect a state of the inductive load in accordance with the drive current detected by the current detection unit, the interterminal voltage detected by the voltage detection unit, and the pulse signal generated by the signal generation unit. The arithmetic logic unit includes: an approximate formula calculation unit configured to calculate an approximate formula of the waveform of the drive current in accordance with a plurality of peak points extracted from the waveform of the drive current; a peak current calculation unit configured to calculate a peak current of the inductive load from the approximate formula calculated by the approximate formula calculation unit; a resistance value calculation unit configured to calculate a resistance value of the inductive load in accordance with the peak current calculated by the peak current calculation unit and the interterminal voltage detected by the voltage detection unit; and an adjustment unit configured to calculate a frequency corresponding to the resistance value calculated by the resistance value calculation unit, and adjust the predetermined frequency pass band of the variable filter so as to allow passage of the calculated frequency.

### BRIEF DESCRIPTION OF THE DRAWINGS

FIG. 1 is a diagram illustrating a configuration of a drive control device according to an embodiment of the present disclosure;

FIG. 2 is a block diagram illustrating an example of a functional configuration of an arithmetic logic unit included in a drive state detection device according to an embodiment of the present disclosure;

FIG. 3 is a flowchart illustrating an example of a procedure of a process performed by the arithmetic logic unit included in the drive state detection device according to the embodiment;

FIG. 4 is a graph describing a calculation method (first example) of a resistance value of a motor performed by the arithmetic logic unit included in the drive state detection device according to the embodiment;

FIG. 5 is a graph describing a calculation method (second example) of the resistance value of the motor performed by the arithmetic logic unit included in the drive state detection device according to the embodiment; and

FIG. 6 is a graph illustrating an example of a waveform of a drive current during locking of a motor in the drive control device according to the embodiment.

### DETAILED DESCRIPTION OF THE INVENTION

There is an existing technique that adjusts a predetermined frequency pass band of a variable filter, in accordance with the frequency of a ripple component in the waveform of a drive current of a motor, so as to include the frequency of the ripple component, thereby converting the ripple component to a pulse signal by passage through the variable filter, and detecting the ripple component converted to the pulse signal.

In this technique, however, in accordance with a change in the resistance value associated with a change in the temperature of the motor, the waveform of the drive current of the motor changes, and the frequency of the ripple component fluctuates accordingly. In order to address this, if the predetermined frequency pass band of the variable filter is not appropriately adjusted, there is a possibility that the frequency of the ripple component is not included, and the ripple component cannot be detected.

A drive control device 10 according to an embodiment of the present disclosure will be described below with reference to the drawings.

### (Configuration of Drive Control Device 10)

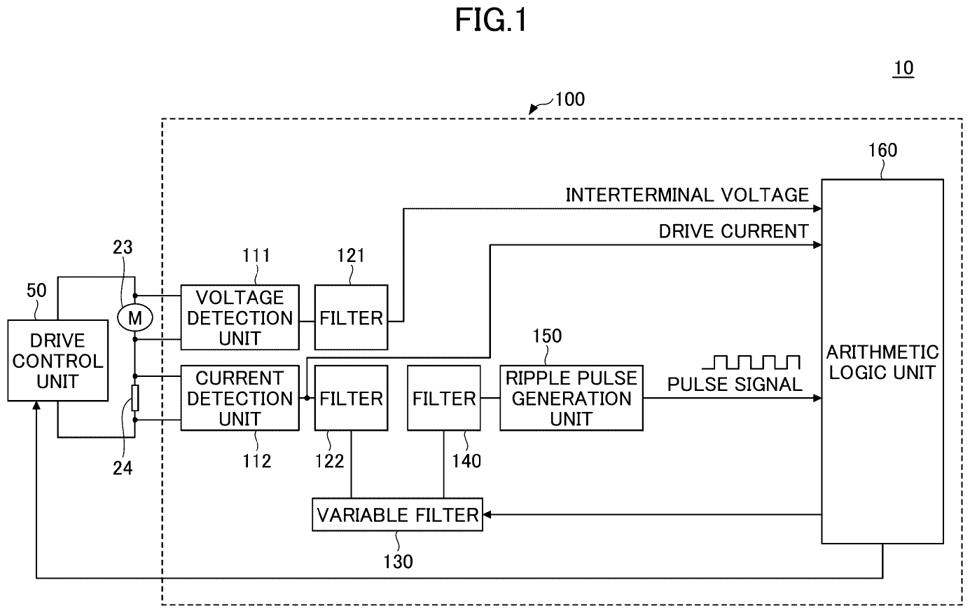

FIG. 1 is a diagram illustrating a configuration of the drive control device 10 according to an embodiment of the present disclosure. The drive control device 10 illustrated in FIG. 1 is a device configured to adjust the posture of a seat included in vehicles, such as an automobile and the like. As illustrated in FIG. 1, the drive control device 10 includes a motor 23, a resistor 24, a drive control unit 50, and a drive state detection device 100.

The motor 23 is an example of “inductive load”. The motor 23 is a direct current (DC) motor configured to adjust the posture of a part of the seat (e.g., a seat base, a backrest, or the like).

The resistor 24 is connected to the motor 23 in series, and is a sensing resistor used for detecting a current of the motor 23.

The drive state detection device 100 is configured to detect an interterminal voltage and a ripple current of the motor 23, and generate a motor state signal indicating the state of the motor in accordance with the detected ripple current. The drive state detection device 100 is configured to output the generated motor state signal to the drive control unit 50.

The drive control unit 50 is configured to adjust the posture of a part of the seat by driving the motor 23 in response to the operation of a switch (not illustrated). At this time, the drive control unit 50 drives the motor 23 in accordance with the motor state signal output from the drive state detection device 100.

The drive control device 10 is not limited to be for adjusting the posture of a seat, and may be used in other applications (e.g., for opening and closing an electric sunroof, for adjusting the angle of an electric door mirror, for opening and closing a power window, and the like).

Here, the configuration of the drive state detection device 100 will be specifically described. As illustrated in FIG. 1, the drive state detection device 100 includes a voltage detection unit 111, a current detection unit 112, a filter 121, a filter 122, a variable filter 130, a filter 140, a ripple pulse generation unit 150, and an arithmetic logic unit 160.

The voltage detection unit 111 is connected to two terminals of the motor 23, and is configured to detect an interterminal voltage during driving of the motor 23. The voltage detection unit 111 is configured to output, to the filter 121, the detected interterminal voltage during driving of the motor 23. As the voltage detection unit 111, for example, a voltage detection circuit including an amplifier can be used.

The current detection unit 112 is configured to detect a drive current during driving of the motor 23. The current detection unit 112 is configured to output, to the arithmetic logic unit 160 and the filter 122, the detected drive current during driving of the motor 23.

The filter 121 is a low pass filter (LPF). The filter 121 is configured to remove noise components, i.e., frequency components higher than a predetermined cutoff frequency, from the interterminal voltage of the motor 23 detected by the voltage detection unit 111. The interterminal voltage of the motor 23 output from the filter 121 is converted to a digital signal by an analog to digital (A/D) converter (not illustrated), and then input to the arithmetic logic unit 160.

The filter 122 is an LPF. The filter 122 is configured to remove noise components, i.e., frequency components higher than a predetermined cutoff frequency, from the drive current during driving of the motor 23 detected by the current detection unit 112, and the remaining drive current is input to the variable filter 130.

The variable filter 130 is a band pass filter (BPF). The variable filter 130 allows passage of frequency components of a predetermined frequency pass band from the drive current during driving of the motor 23 output from the filter 122. The drive current during driving of the motor 23 output from the variable filter 130 (the drive current after passage through the variable filter) is input to the filter 140. Through the arithmetic logic unit 160, it is possible to control the predetermined frequency pass band of the variable filter 130.

The filter 140 is a high pass filter (HPF). The filter 140 is configured to remove noise components, i.e., frequency components lower than a predetermined cutoff frequency, from the drive current during driving of the motor 23 output from the variable filter 130. The drive current during driving of the motor 23 output from the filter 140 is input to the ripple pulse generation unit 150.

The ripple pulse generation unit 150 is an example of “signal generation unit”. The ripple pulse generation unit 150 is configured to detect a ripple component included in the drive current during driving of the motor 23 output from the filter 140. The ripple pulse generation unit 150 is configured to convert the detected ripple component to a pulse signal, and output the pulse signal to the arithmetic logic unit 160.

The arithmetic logic unit 160 is configured to detect the state of the motor 23 in accordance with the drive current during driving of the motor 23 detected by the current detection unit 112, the interterminal voltage during driving of the motor 23 detected by the voltage detection unit 111, and the pulse signal generated by the ripple pulse generation unit 150. Then, the arithmetic logic unit 160 is configured to output, to the drive control unit 50, a motor state signal indicating the detected state of the motor 23. For example, the arithmetic logic unit 160 detects the rotation number of the motor, which is an example of the state of the motor 23, in accordance with the pulse signal generated by the ripple pulse generation unit 150. Then, the arithmetic logic unit 160 outputs, to the drive control unit 50, the motor state signal in accordance with the detected rotation number of the motor 23.

(Example of Functional Configuration of Arithmetic Logic Unit 160)

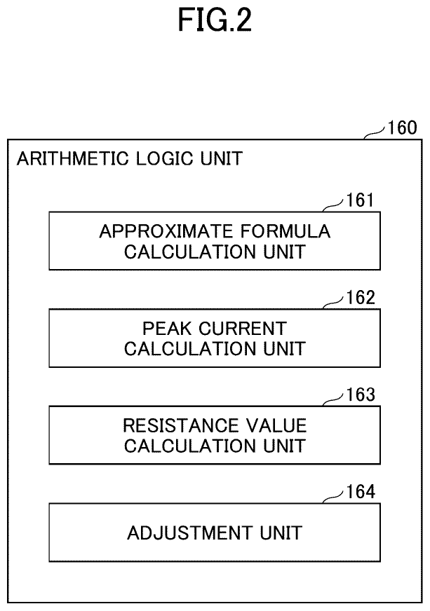

FIG. 2 is a block diagram illustrating an example of a functional configuration of the arithmetic logic unit 160 included in the drive state detection device 100 according to an embodiment of the present disclosure. As illustrated in FIG. 2, the arithmetic logic unit 160 includes an approximate formula calculation unit 161, a peak current calculation unit 162, a resistance value calculation unit 163, and an adjustment unit 164.

The approximate formula calculation unit 161 is configured to extract a plurality of peak points from the waveform of the drive current during driving of the motor 23 detected by the current detection unit 112. Then, the approximate formula calculation unit 161 is configured to calculate an approximate formula (a formula of an exponential curve) of the waveform of the drive current during driving of the motor 23 in accordance with the plurality of extracted peak points.

As an example, the approximate formula calculation unit 161 extracts a plurality of local minimum points from the waveform of the drive current during driving of the motor 23 detected by the current detection unit 112. Then, the approximate formula calculation unit 161 calculates an approximate formula of the waveform of the drive current during driving of the motor 23 in accordance with the plurality of extracted local minimum points.

As another example, the approximate formula calculation unit 161 extracts a plurality of local maximum points from the waveform of the drive current during driving of the motor 23 detected by the current detection unit 112. Then, the approximate formula calculation unit 161 calculates an approximate formula of the waveform of the drive current during driving of the motor 23 in accordance with the plurality of extracted local maximum points.

The peak current calculation unit 162 is configured to calculate a peak current of the motor 23 from the approximate formula of the waveform of the drive current during driving of the motor 23 calculated by the approximate formula calculation unit 161.

The resistance value calculation unit 163 is configured to calculate a resistance value of the motor 23 in accordance with the peak current of the motor 23 calculated by the peak current calculation unit 162 and the interterminal voltage during driving of the motor 23 detected by the voltage detection unit 111.

The adjustment unit 164 is configured to adjust a predetermined frequency pass band of the variable filter 130 in accordance with the resistance value of the motor 23 calculated by the resistance value calculation unit 163.

Specifically, the adjustment unit 164 calculates, in accordance with the resistance value of the motor 23 calculated by the resistance value calculation unit 163, the frequency of the ripple component corresponding to the resistance value. The adjustment unit 164 adjusts the predetermined frequency pass band of the variable filter 130 such that the calculated frequency of the ripple component is included in the predetermined frequency pass band. By adjusting the predetermined frequency pass band of the variable filter 130, it is possible to reliably allow passage of the calculated frequency of the ripple component included in the waveform of the drive current.

The arithmetic logic unit 160 is implemented by an integrated circuit (IC), such as a microcomputer or the like. The respective functional units of the arithmetic logic unit 160 are implemented by a processor (e.g., a central processing unit (CPU), a micro processing unit (MPU), or the like) that executes programs stored in a memory (e.g., a dynamic random access memory (DRAM), a static random access memory (SRAM), a flash memory, or the like) in the IC.

(Example of Procedure of Process performed by Arithmetic Logic Unit 160)

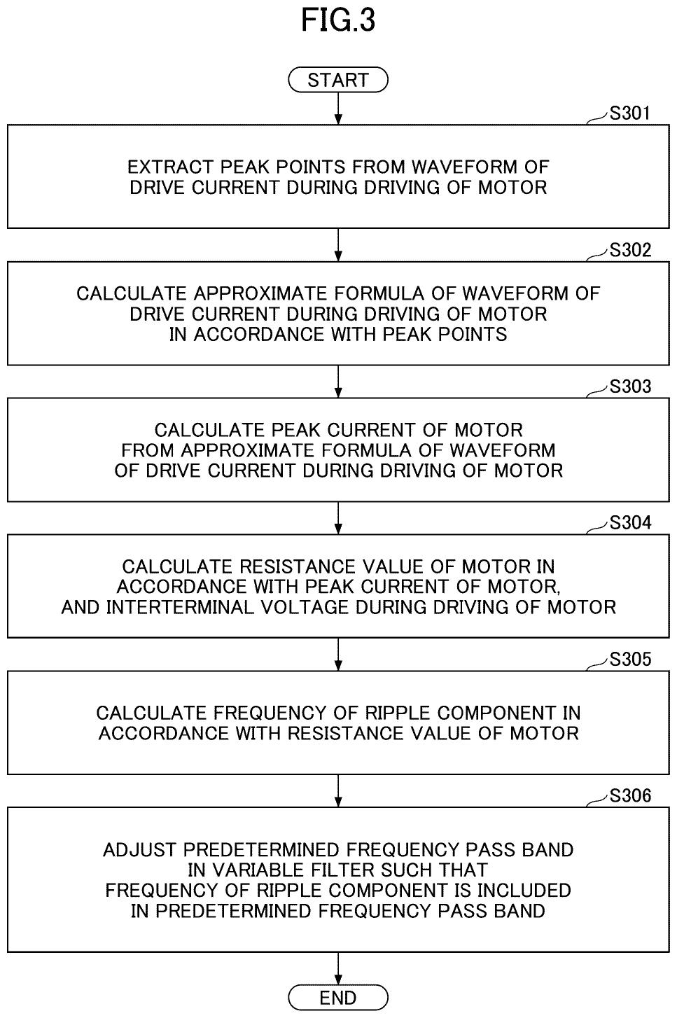

FIG. 3 is a flowchart illustrating an example of a procedure of a process performed by the arithmetic logic unit 160 included in the drive state detection device 100 according to the embodiment.

First, the approximate formula calculation unit 161 extracts a plurality of peak points (local minimum points or local maximum points) from the waveform of the drive current during driving of the motor 23 detected by the current detection unit 112 (step S301).

Next, the approximate formula calculation unit 161 calculates an approximate formula of the waveform of the drive current during driving of the motor 23 in accordance with the plurality of peak points extracted in step S301 (step S302).

Next, the peak current calculation unit 162 calculates a peak current of the motor 23 from the approximate formula of the waveform of the drive current during driving of the motor 23 calculated in step S302 (step S303).

Next, the resistance value calculation unit 163 calculates a resistance value of the motor 23 in accordance with the peak current of the motor 23 calculated in step S303 and the interterminal voltage during driving of the motor 23 detected by the voltage detection unit 111 (step S304).

Next, the adjustment unit 164 calculates, in accordance with the resistance value of the motor 23 calculated in step S304, a frequency of the ripple component corresponding to the resistance value (step S305).

Next, the adjustment unit 164 adjusts a predetermined frequency pass band of the variable filter 130 such that the frequency of the ripple component calculated in step S305 is included in the predetermined frequency pass band (step S306).

(Calculation Method (first example) of Resistance Value of Motor 23 performed by Arithmetic Logic Unit 160)

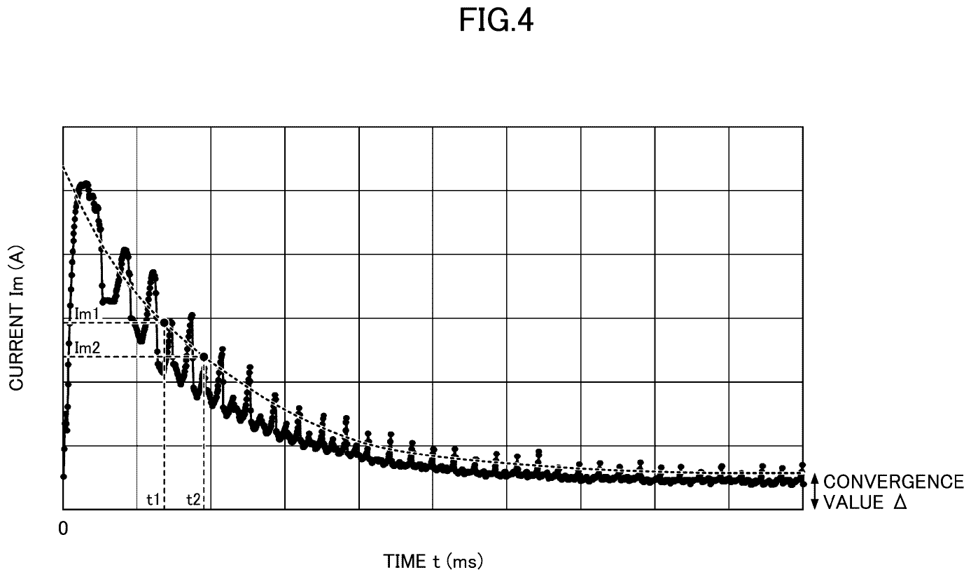

FIG. 4 is a graph describing a calculation method (first example) of the resistance value of the motor 23 performed by the arithmetic logic unit 160 included in the drive state detection device 100 according to the embodiment.

In the graph illustrated in FIG. 4, a waveform of the drive current during driving of the motor 23 detected by the current detection unit 112 is denoted by a solid line, and an exp curve representing an approximate formula of the waveform of the drive current during driving of the motor 23 calculated by the approximate formula calculation unit 161 is denoted by a dotted line.

Here, the approximate formula of the waveform of the drive current during driving of the motor 23 calculated by the approximate formula calculation unit 161 is expressed by the following mathematical formula (1). The convergence value A included in the mathematical formula (1) is an example of “steady-state value”, and can be the current value extracted from the waveform of the drive current when the motor 23 is in a steady drive state (i.e., a state in which the motor 23 is stably rotating).

$${I}_{m} ( T ) = A \cdot {e}^{- \frac{t}{T}} + Δ \qquad Mathematical Formula ( 1 )$$

The mathematical formula (1) is converted to the following mathematical formula (2).

$$A = ImPeak - Δ \qquad Mathematical Formula ( 2 )$$

The peak current calculation unit 162 can calculate the peak current ImPeak at the time of start of the motor 23 (i.e., a rush current) according to the following mathematical formula (3), which is derived from the mathematical formulae (1) and (2). Im (t) denotes a current value at time t at which the waveform of the drive current is the local maximum point.

$$ImPeak = ( Im ( t ) - Δ ) \times Exp ( \frac{t}{T} ) + Δ \qquad Mathematical Formula ( 3 )$$

Here, when as illustrated in FIG. 4, the current value at time t1 (the local maximum point of the waveform of the drive current) is Im1, and the current value at time t2 (the local maximum point of the waveform of the drive current) is Im2, the mathematical formula (3) becomes the following mathematical formulae (4) and (5).

$$ImPeak = ( Im 1 - Δ ) \times Exp ( \frac{t 1}{T} ) + Δ \qquad Mathematical Formula ( 4 )$$

$$ImPeak = ( Im 2 - Δ ) \times Exp ( \frac{t 2}{T} ) + Δ \qquad Mathematical Formula ( 5 )$$

Therefore, the peak current calculation unit 162 can calculate T in the mathematical formula (3) from the following mathematical formula (6), which is derived from the mathematical formulae (4) and (5).

$$T = \frac{( t 2 - t 1 )}{ln ( \frac{Im 1 - Δ}{Im 2 - Δ} )} \qquad Mathematical Formula ( 6 )$$

The resistance value calculation unit 163 can calculate resistance value Rm′ of the motor 23, according to the following mathematical formula (7), in accordance with the peak current ImPeak at the time of start of the motor 23 calculated by the mathematical formula (3) and the interterminal voltage Vm during driving of the motor 23 detected by the voltage detection unit 111.

$${R}_{m}^{′} = \frac{{V}_{m}}{{I}_{m \_ peak}} \qquad Mathematical Formula ( 7 )$$

The adjustment unit 164 can calculate, in accordance with the resistance value Rm′ of the motor 23 calculated by the mathematical formula (7), frequency f of a ripple component corresponding to the resistance value Rm′, according to the following mathematical formula (8).

$$f = ( - {Rm}^{′} * Im + Eb ) * s / Ke \qquad Mathematical Formula ( 8 )$$

In the mathematical formula (8), Eb denotes a power supply voltage [V], Im denotes a motor current [A], Ke denotes a power generation coefficient [V/rps], and s denotes the number of ripples per rotation of the motor.

The adjustment unit 164 calculates the frequency f of the ripple component according to the mathematical formula (8), thereby being able to calculate suitable frequency f of a ripple component in accordance with the resistance value Rm′ of the motor 23.

The adjustment unit 164 adjusts the predetermined frequency pass band of the variable filter 130 such that the frequency f of the ripple component calculated according to the mathematical formula (8) is included in the predetermined frequency pass band of the variable filter 130. This can reliably allow passage, through the variable filter 130, of the ripple component included in the waveform of the drive current during driving of the motor 23, i.e., can prevent miss detection of the ripple component.

As described above, the arithmetic logic unit 160 included in the drive state detection device 100 according to the embodiment includes: the approximate formula calculation unit 161 configured to calculate an approximate formula of the waveform of the drive current in accordance with a plurality of peak points extracted from the waveform of the drive current; the peak current calculation unit 162 configured to calculate a peak current of the motor 23 from the approximate formula calculated by the approximate formula calculation unit 161; the resistance value calculation unit 163 configured to calculate a resistance value of the motor 23 in accordance with the peak current calculated by the peak current calculation unit 162 and the interterminal voltage detected by the voltage detection unit 111; and the adjustment unit 164 configured to adjust the predetermined frequency pass band of the variable filter 130 in accordance with the resistance value calculated by the resistance value calculation unit 163.

Thus, the drive state detection device 100 according to the embodiment can appropriately adjust the frequency pass band of the variable filter 130 in accordance with the change in the waveform of the drive current caused by the change in the temperature of the motor 23 so as to allow passage of the frequency of the ripple component included in the waveform of the drive current.

In existing methods of calculating the resistance value of the motor 23 in accordance with the waveform of the peak current of the motor 23, the waveform of the peak current varies with the positions of the brush and the commutator of the motor 23. Thus, the peak current of the motor 23 cannot be calculated with high accuracy.

On the other hand, the drive state detection device 100 according to the embodiment calculates the resistance value of the motor 23 from the approximate formula of the waveform of the drive current in accordance with the plurality of peak points extracted from the waveform of the drive current of the motor 23. Thus, the peak current of the motor 23 can be calculated with high accuracy.

Also, according to the drive state detection device 100 according to the embodiment, the approximate formula calculation unit 161 calculates an approximate formula including a convergence value 4, which is a steady-state value of the current value extracted from the waveform of the drive current when the motor 23 is in a steady drive state.

Thus, the drive state detection device 100 according to the embodiment can make an approximate formula, calculated by the approximate formula calculation unit 161, along the waveform of the drive current during driving of the motor 23 as illustrated in FIG. 4. Therefore, the peak current at the time of start of the motor 23 can be calculated with high accuracy.

In the first example illustrated in FIG. 4, the approximate formula calculation unit 161 calculates an approximate formula (the mathematical formula (3)) of the waveform of the drive current during driving of the motor 23 in accordance with a plurality of local maximum points of the waveform of the drive current. Thus, the calculated approximate formula can be along the waveform of the drive current during driving of the motor 23 as illustrated in FIG. 4. Therefore, the peak current at the time of start of the motor 23 can be calculated with high accuracy.

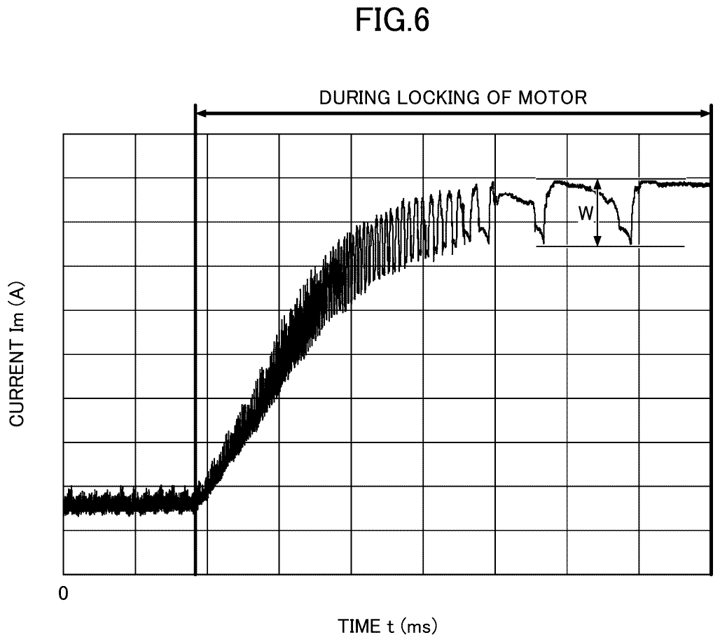

In the first example illustrated in FIG. 4, the approximate formula expressed by the mathematical formula (3) may be further improved such that W (an amplitude of the current value during locking of the motor 23 (see FIG. 6))=2 (an example of a lock current value in accordance with the amplitude of the current value during locking of the motor 23) is subtracted. Thus, the resistance value calculation unit 163 can calculate the peak current ImPeak at the time of start of the motor 23 with higher accuracy according to the mathematical formula (3) that is improved in the above-described manner.

(Calculation Method (second example) of Resistance Value of Motor 23 performed by Arithmetic Logic Unit 160)

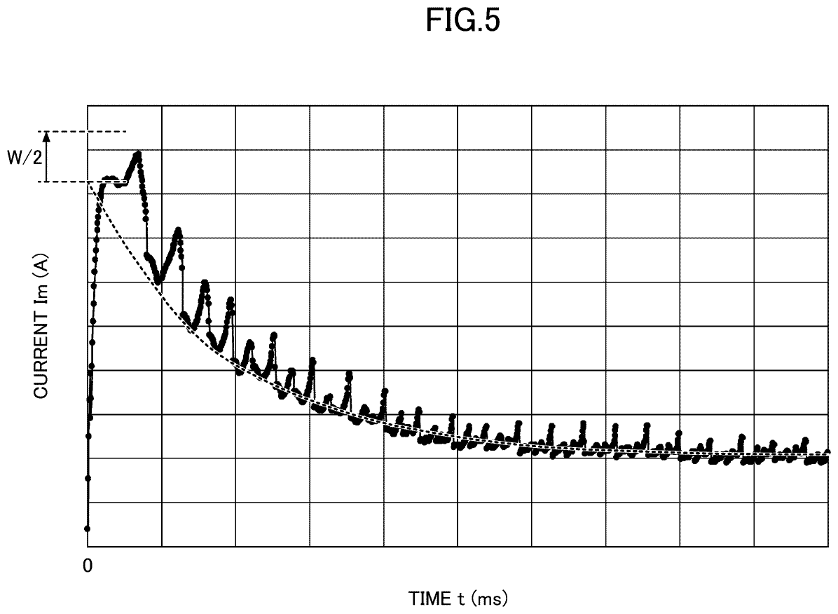

FIG. 5 is a graph describing a calculation method (second example) of the resistance value of the motor 23 performed by the arithmetic logic unit 160 included in the drive state detection device 100 according to the embodiment.

In the graph illustrated in FIG. 5, similar to the graph illustrated in FIG. 4, a waveform of the drive current during driving of the motor 23 detected by the current detection unit 112 is denoted by a solid line, and an exp curve representing an approximate formula of the waveform of the drive current during driving of the motor 23 calculated by the approximate formula calculation unit 161 is denoted by a dotted line.

The second example illustrated in FIG. 5 differs from the first example illustrated in FIG. 4 in that the approximate formula calculation unit 161 calculates the following mathematical formula (9), which is an approximate formula of the waveform of the drive current during driving of the motor 23, in accordance with a plurality of local minimum points of the waveform of the drive current. In the mathematical formula (9), Im bottom (t) denotes the current value at time t at which the waveform of the drive current is the local minimum point.

$$Mathematical Formula ( 9 )$$

$$ImPeak = ( Im \_ bottom ( t ) - Δ ) \times Exp ( \frac{t}{τ} ) + Δ + W / 2$$

In the second example illustrated in FIG. 5, the approximate formula calculation unit 161 can calculate an exp curve along a plurality of local minimum points of the waveform of the drive current as an approximate formula of the waveform of the drive current during driving of the motor 23.

The approximate formula expressed by the mathematical formula (9) differs from the approximate formula expressed by the mathematical formula (3) in that W (an amplitude of the current value during locking of the motor 23 (see FIG. 6))=2 (an example of a lock current value in accordance with the amplitude of the current value during locking of the motor 23) is added.

In the first example illustrated in FIG. 4, the approximate formula calculation unit 161 calculates an approximate formula (the mathematical formula (3)) of the waveform of the drive current during driving of the motor 23 in accordance with a plurality of local maximum points of the waveform of the drive current. In this case, when the amplitude varies between a plurality of ripple components, the approximate formula calculated in accordance with the plurality of local maximum points does not become along the waveform of the drive current during driving of the motor 23, and the peak current at the time of start of the motor 23 cannot be calculated with high accuracy.

On the other hand, in the second example illustrated in FIG. 5, the approximate formula calculation unit 161 calculates an approximate formula (the mathematical formula (9)) of the waveform of the drive current during driving of the motor 23 in accordance with a plurality of local minimum points of the waveform of the drive current. Thus, even if the amplitude varies between a plurality of ripple components, the approximate formula calculated in accordance with the plurality of local minimum points becomes along the waveform of the drive current during driving of the motor 23. Therefore, the peak current at the time of start of the motor 23 can be calculated with high accuracy.

In the second example illustrated in FIG. 5, the approximate formula (the mathematical formula (9)) of the waveform of the drive current during driving of the motor 23 is such that W (an amplitude of the current value during locking of the motor 23)+2 (an example of a lock current value in accordance with the amplitude of the current value during locking of the motor 23) is added. The resistance value calculation unit 163 can calculate the peak current ImPeak at the time of start of the motor 23 with high accuracy according to the mathematical formula (9).

### (Example of Waveform of Drive Current During Locking of Motor)

FIG. 6 is a graph illustrating an example of a waveform of a drive current during locking of the motor 23 in the drive control device 10 according to the embodiment.

In the present embodiment, a duration from a steady rotation state of the motor 23 until an actually locked state of the motor 23 is defined as “during locking of the motor”. As illustrated in FIG. 6, during locking of the motor 23, the current value of the drive current of the motor 23 gradually increases from the current value in the steady rotation state, and then becomes a substantially constant current value. At this time, the current value of the drive current of the motor 23 has amplitude W between the peak value (local maximum value) and the immediately preceding peak value (local minimum value) as illustrated in FIG. 6. In the mathematical formula (9), this amplitude W is used to calculate an approximate formula of the waveform of the drive current during driving of the motor 23. When the motor 23 is actually locked, the current value of the drive current of the motor 23 has no amplitude fluctuation as illustrated in FIG. 6.

Although the embodiments of the present invention have been described above in detail, the present invention is not limited to these embodiments, and various modifications or alterations may be possible within the scope of the intent of the present invention recited in the claims.

For example, according to the drive state detection device 100 according to the embodiment, the approximate formula calculation unit 161 may extract local maximum points and local minimum points from the waveform of the drive current during driving of the motor 23, and calculate an approximate formula of the waveform of the drive current during driving of the motor 23 in accordance with the average values of the extracted local maximum points and local minimum points.

In this case, the drive state detection device 100 according to the embodiment can make an approximate formula, calculated by the approximate formula calculation unit 161, along the waveform of the drive current during driving of the motor 23, and thus can calculate a peak current at the time of start of the motor 23 with high accuracy.

According to the drive state detection device according to the embodiment of the present disclosure, the frequency pass band of the variable filter can be appropriately adjusted in accordance with the change in the waveform of the drive current caused by the change in the temperature of the inductive load.

What is claimed is:

1. A drive state detection device, comprising:
a current detection unit configured to detect a drive current during driving of an inductive load;
a voltage detection unit configured to detect an interterminal voltage during the driving of the inductive load;
a variable filter configured to allow passage of a component of a predetermined frequency pass band, the component being of the drive current detected by the current detection unit;
a signal generation unit configured to generate a pulse signal from a waveform of the drive current after the passage through the variable filter; and
an arithmetic logic unit configured to detect a state of the inductive load in accordance with the drive current detected by the current detection unit, the interterminal voltage detected by the voltage detection unit, and the pulse signal generated by the signal generation unit,
the arithmetic logic unit including a memory and a processor coupled to the memory, the processor being configured to:
calculate an approximate formula of the waveform of the drive current in accordance with a plurality of peak points extracted from the waveform of the drive current,
calculate a peak current of the inductive load from the calculated approximate formula,
calculate a resistance value of the inductive load in accordance with the calculated peak current and the detected interterminal voltage, and
calculate a frequency corresponding to the calculated resistance value, and adjust the predetermined frequency pass band of the variable filter so as to allow passage of the calculated frequency.

2. The drive state detection device according to claim 1, wherein
the processor is configured to
calculate the approximate formula of the waveform of the drive current, the approximate formula including a steady-state value extracted from the waveform of the drive current in a state in which the inductive load is in a steady drive state.

3. The drive state detection device according to claim 1, wherein
the processor is configured to
calculate the approximate formula of the waveform of the drive current in accordance with:
the plurality of peak points extracted from the waveform of the drive current; and
a lock current value in accordance with an amplitude of the current value during locking of the inductive load.

4. The drive state detection device according to claim 1, wherein
the peak points are local minimum points.

5. The drive state detection device according to claim 4, wherein
the processor is configured to
calculate the approximate formula of the waveform of the drive current in accordance with the local minimum points extracted from the waveform of the drive current, a lock current value in accordance with an amplitude of the current value during locking of the inductive load being added to the approximate formula.

6. The drive state detection device according to claim 1, wherein
the peak points are local maximum points.

7. The drive state detection device according to claim 6, wherein
the processor is configured to
calculate the approximate formula of the waveform of the drive current in accordance with the local maximum points extracted from the waveform of the drive current, a lock current value in accordance with an amplitude of the current value during locking of the inductive load being subtracted from the approximate formula.

8. The drive state detection device according to claim 1, wherein
the peak points are local maximum points and local minimum points, and
the processor is configured to
calculate the approximate formula of the waveform of the drive current in accordance with average values of the local maximum points and the local minimum points that are extracted from the waveform of the drive current.
